(19) United States
(12) Patent Application Publication
(10) Pub. No.: US 2020/0400544 A1
(43) Pub. Date: Dec. 24, 2020

(54) INTEGRATED FILTER-BASED PARTICULATE MATTER SENSORS

(71) Applicants: ams International AG, Jona (CH); Technische Universität Graz, Graz (AT)

(72) Inventors: Harald Etschmaier, Eindhoven (NL); Georg Roehrer, Eindhoven (NL); Anderson Singulani, Eindhoven (NL); Hubert Enichlmair, Eindhoven (NL); Jong-Mun Park, Eindhoven (NL); Alexander Bergmann, Eindhoven (NL); Paul Maierhofer, Eindhoven (NL)

(21) Appl. No.: 16/772,457

(22) PCT Filed: Dec. 13, 2018
(86) PCT No.: PCT/EP2018/084759

§ 371 Date: Jun. 12, 2020

Related U.S. Application Data
(60) Provisional application No. 62/599,138, filed on Dec. 15, 2017.

(51) Int. Cl. G01N 15/06; G01N 1/22; H05K 1/02

(52) U.S. Cl. CPC G01N 15/0618; H05K 5/0052; H05K 1/0274; G01N 1/2205

(57) ABSTRACT

An apparatus for sensing particulate matter in a fluid includes a substrate; and an integrated circuit electrically connected to the substrate, the integrated circuit including a photodetector. The apparatus includes a filter assembly including a particle filter aligned with the photodetector, and a filter housing for the particle filter, the filter housing defining a flow path for fluid through the particle filter. The apparatus includes a light source electrically connected to the substrate and positioned to illuminate the particle filter.

### CLAIM OF PRIORITY

This application claims priority to U.S. Patent Application Ser. No. 62/599,138, filed on Dec. 15, 2017, the contents of which are incorporated here by reference in their entirety.

This application incorporates by reference the entire contents of the following patent applications: U.S. Patent Application Ser. No. 62/599,156, filed on Dec. 15, 2017; U.S. Patent Application Ser. No. 62/599,168, filed on Dec. 15, 2017; and U.S. Patent Application Ser. No. 62/720,492, filed on Aug. 21, 2018.

### BACKGROUND

There are various types of particulate matter sensors, including sensors based on optical scattering, sensors based on light absorption of filters, diffusion charging based sensors, sensors based on gravimetric filter analysis, beta attenuation sensors, tapered element oscillating microbalance sensors, and photoacoustic sensors.

### SUMMARY

In an aspect, an apparatus for sensing particulate matter in a fluid includes a substrate; and an integrated circuit electrically connected to the substrate, the integrated circuit including a photodetector. The apparatus includes a filter assembly including a particle filter aligned with the photodetector, and a filter housing for the particle filter, the filter housing defining a flow path for fluid through the particle filter. The apparatus includes a light source electrically connected to the substrate and positioned to illuminate the particle filter.

Embodiments can include one or more of the following features.

The filter assembly is affixed to the integrated circuit.

The filter assembly is affixed to the substrate.

The substrate includes a printed circuit board.

The light source is disposed on the substrate. The apparatus includes multiple light sources disposed on the substrate, a first light source disposed to a first side of the filter assembly and a second light source disposed to a second side of the filter assembly. The apparatus includes multiple light sources disposed on the substrate; and multiple photodetectors disposed on the substrate. Each of the multiple light sources is positioned to illuminate each photodetector with light of a substantially similar intensity.

The apparatus includes multiple photodetectors disposed on the substrate, a first photodetector disposed to a first side of the filter assembly and a second photodetector disposed to a second side of the filter assembly.

The apparatus includes a sensor housing affixed to the substrate. The sensor housing and the substrate define an interior space in which the integrated circuit, the filter assembly, and the light source are disposed. An interior surface of the sensor housing has a reflectivity of at least 30% to light emitted by the light source. The apparatus includes a layer of a reflective material disposed on an interior surface of the sensor housing. The light source is positioned to illuminate the sensor housing such that light reflected from the sensor housing illuminates the particle filter. The light source is disposed on an interior wall of the sensor housing. A cross section of the sensor housing has a curved profile.

The integrated circuit includes a second photodetector. The filter assembly includes a reference particle filter aligned with the second photodetector. The filter housing does not define a flow path for fluid through the reference particle filter.

The integrated circuit is electrically connected to the substrate by through silicon vias, a backside redistribution layer, and solder balls. The apparatus includes an underfill material disposed between the integrated circuit and the substrate. The apparatus includes a fillet disposed at one or more edges of the integrated circuit.

The light source includes a broad spectrum light source. The photodetector includes a first region configured to detect a first wavelength emitted from the broad spectrum light source and a second region configured to detect a second wavelength emitted from the broad spectrum light source.

The light source is a first light source configured to emit light a first wavelength. The apparatus includes a second light source configured to emit light at a second wavelength. The photodetector is configured to detect the first wavelength and the second wavelength.

In an aspect, a method for detecting particulate matter in a fluid includes flowing a fluid containing particulate matter through a flow path defined by a filter housing, including flowing the fluid through a particle filter disposed on the filter housing. The method includes illuminating the particle filter with light from a light source electrically connected to a substrate. The method includes detecting an optical characteristic of the particle filter by a photodetector formed in an integrated circuit electrically connected to the substrate, the photodetector being aligned with the particle filter.

Embodiments can include one or more of the following features.

Detecting an optical characteristic of the particle filter includes detecting an absorption of the particle filter.

Detecting an optical characteristic of the particle filter includes detecting a rate of change in the optical characteristic.

Illuminating the particle filter with light includes reflecting the light from the light source off of an interior wall of a sensor housing, the sensor housing and the substrate defining an interior space in which the integrated circuit, the filter housing, and the light source are disposed.

The method includes stopping the flow of fluid when a threshold change in the optical characteristic of the particle filter is detected.

In an aspect, a method for making an apparatus for sensing particulate matter in a fluid includes electrically connecting an integrated circuit including a photodetector to a printed circuit board substrate. The method includes disposing a filter housing on the printed circuit board substrate such that a particle filter disposed on the filter housing is aligned with the photodetector of the integrated circuit, the filter housing defining a flow path for fluid through the particle filter. The method includes electrically connecting a light source to the printed circuit board substrate such that the light source is positioned to illuminate the particle filter.

Embodiments can include one or more of the following features.

The method includes disposing an underfill material between the integrated circuit and the printed circuit board substrate.

The method includes disposing the light source on the printed circuit board substrate.

The method includes gluing the particle filter to the filter housing.

Disposing the filter housing on the printed circuit board substrate includes affixing the filter housing to the integrated circuit including the photodetector. Affixing the filter housing to the integrated circuit includes gluing the filter housing to the integrated circuit.

Disposing the filter housing on the printed circuit board substrate includes gluing the filter housing to the printed circuit board substrate.

The method includes forming the filter housing by a molding process. Forming the filter housing includes forming multiple cavities in the filter housing.

The method includes affixing a sensor housing to the printed circuit board substrate such that the sensor housing and the printed circuit board substrate define an interior space in which the integrated circuit, the filter housing, and the light source are disposed. The method includes forming the sensor housing by a molding process. The method includes disposing the light source on an interior wall of the sensor housing. The integrated circuit includes a second photodetector. The method includes affixing the filter housing to the integrated circuit such that a reference particle filter disposed on the filter housing is aligned with the second photodetector.

The method includes affixing a molded cover piece onto the filter housing.

Affixing a filter housing to an integrated circuit includes affixing a housing piece including multiple filter housings to a wafer including multiple integrated circuits such that each of one or more of the filter housings is aligned with a corresponding integrated circuit. The method includes singulating the wafer into multiple pieces, each piece including an integrated circuit with affixed filter housing. Electrically connecting the integrated circuit to a printed circuit board substrate includes electrically connecting the multiple pieces each including an integrated circuit to the printed circuit board substrate. The method includes singulating the printed circuit board substrate into multiple pieces.

In an aspect, a sensing system for sensing particulate matter in a fluid includes an inlet microfluidic channel. The sensing system includes a particle sensing apparatus including a substrate; an integrated circuit electrically connected to the substrate, the integrated circuit including a photodetector; a filter assembly including a particle filter aligned with the photodetector, and a filter housing for the particle filter, the filter housing defining a sensing microfluidic channel for fluid through the particle filter, the sensing microfluidic channel being fluidically connected to the inlet microfluidic channel; and a light source electrically connected to the substrate and positioned to illuminate the particle filter. The sensing system includes an outlet fluidically connected to the sensing microfluidic channel; and a fluid circulation component configured to induce fluid flow from the inlet microfluidic channel, through the sensing microfluidic channel, and out the outlet.

Embodiments can include one or more of the following features.

The fluid circulation component includes one or more of a pump, a fan, a heater, and an ultrasonic nozzle.

The particulate matter sensors described here can have one or more of the following advantages. The particulate matter sensors are compact, and can be integrated into compact particulate matter sensing systems for use with mobile device based air quality sensing. The particulate matter sensors and sensing systems can be manufactured at low cost per sensor unit by using semiconductor manufacturing and packaging techniques.

### BRIEF DESCRIPTION OF DRAWINGS

FIG. 1 is a diagram of a particulate matter sensor.

FIG. 2A is a top view of a particulate matter sensor.

FIGS. 2B-2D are cross sections of the particulate matter sensor of FIG. 2A.

FIGS. 3A and 3B are diagrams of a particulate matter sensor.

FIG. 4 is a diagram of a particulate matter sensor.

FIG. 5 is a diagram of a particulate matter sensor.

FIGS. 6-8 are flow charts.

FIGS. 9A and 9B are exploded views of a particulate matter sensor.

FIGS. 10 and 11 are diagrams of particulate matter sensor systems.

FIGS. 12A and 12B are diagrams of a particulate matter sensor system.

FIG. 13 is a diagram of a mobile computing device.

### DETAILED DESCRIPTION

We describe here integrated particulate matter sensors that detect particulate matter present in a fluid by measuring an optical characteristic of a filter. Fluid flowing through the filter causes accumulation of particulate matter from the fluid onto the filter, changing an optical characteristic such as an absorption of light by the filter. The filter is illuminated by a light source, such as a light emitting diode, and light transmitted through the filter is measured by an integrated circuit photodiode affixed to the filter. The particulate matter sensors described here can be integrated into compact particulate matter sensing systems that can be used, e.g., to carry out mobile device based air quality sensing.

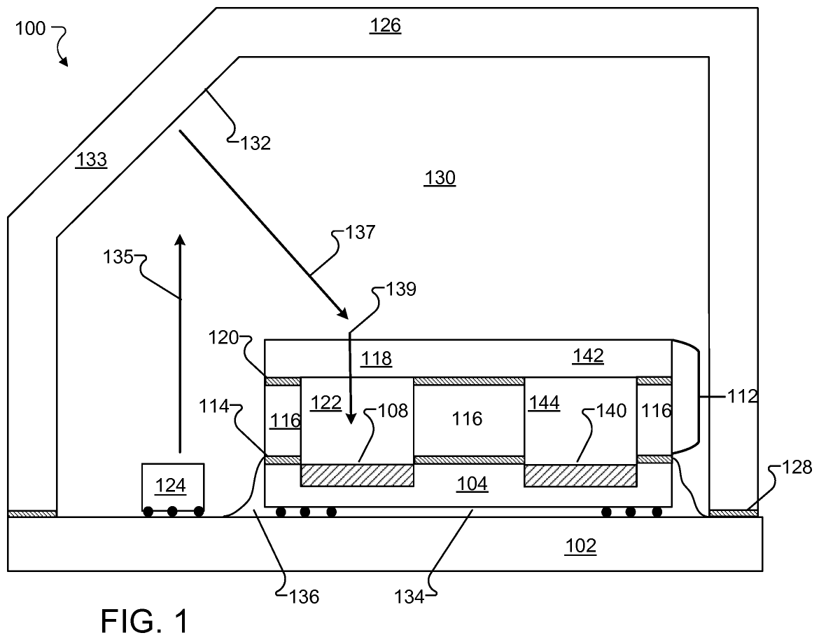

Referring to FIG. 1, an example particulate matter sensor 100 includes a substrate 102, such as a printed circuit board. An integrated circuit 104, such as a silicon-based integrated circuit, e.g., a complementary metal-oxide-semiconductor (CMOS) integrated circuit, is electrically connected to the substrate 102. In some examples, the integrated circuit 104 can be connected to the substrate 102 by through silicon vias (TSVs), a backside redistribution layer, and solder balls. In some examples, the integrated circuit 104 can be connected to the substrate by wire bonding. Other types of connections can also be used. The integrated circuit 104 includes a photodetector 108, such as a photo diode, a pinned photo diode, a pin photodiode, an avalanche photo diode, a single photon avalanche photo diode, or another type of photo diode. In some examples, e.g., to reduce cross talk, the photodetector 108 can be a photodetector that has a low sensitivity to carriers generated within the semiconductor body of the integrated circuit 104, such as a substrate isolated photo diode (e.g., p+ in an n-well for a p-type integrated circuit body).

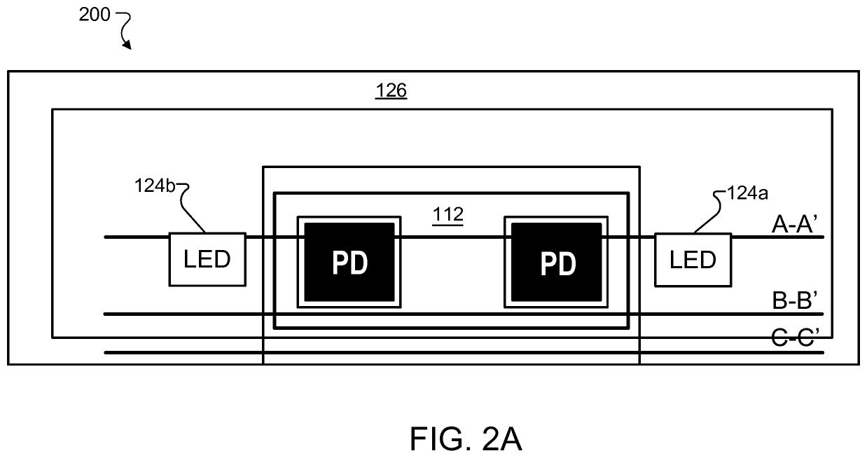

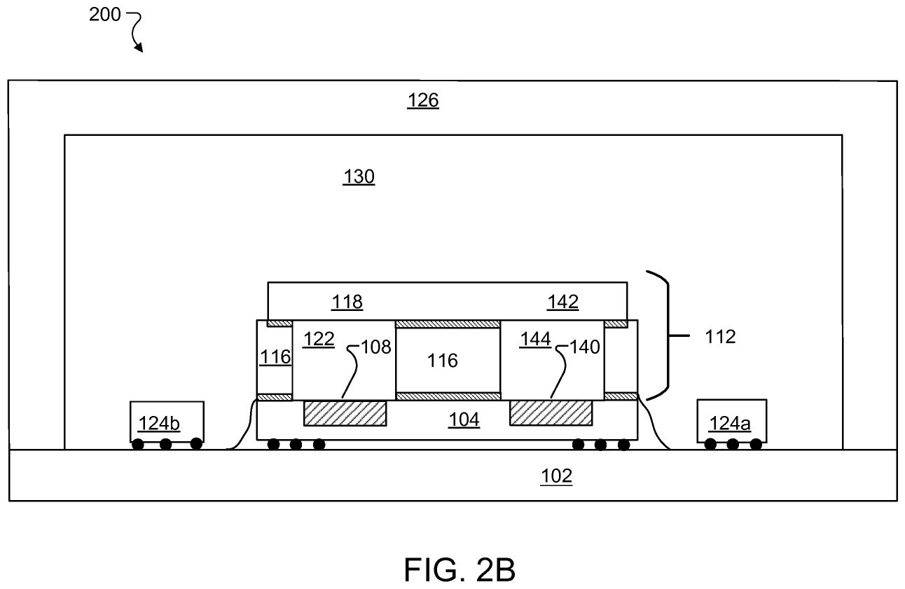

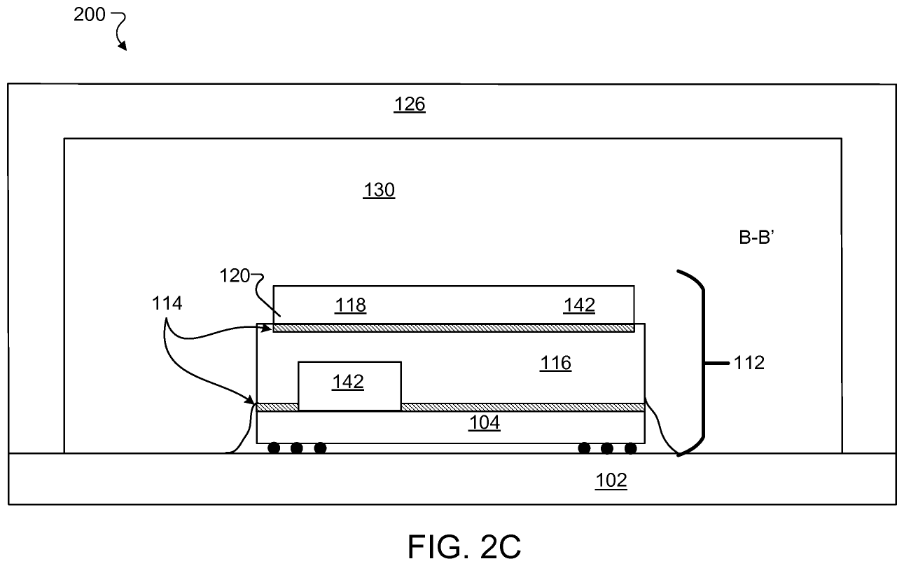

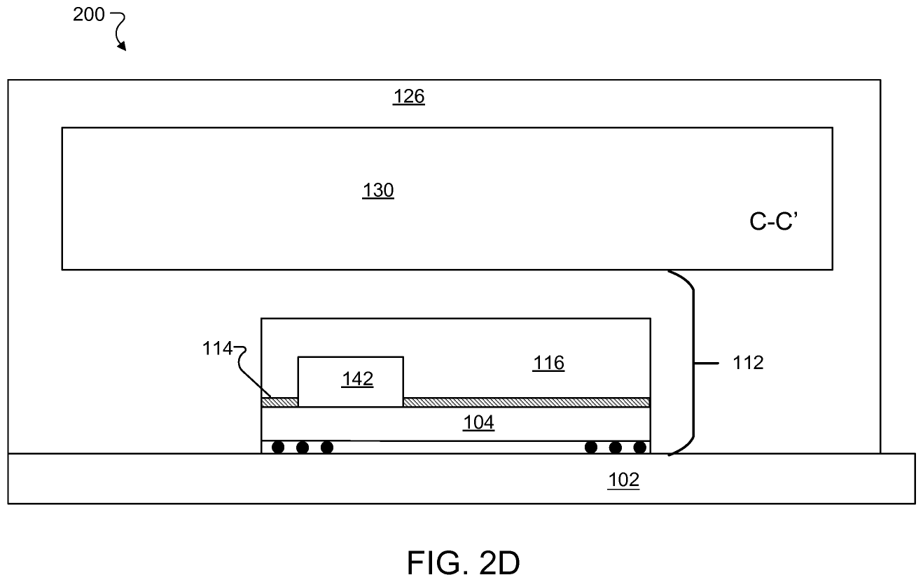

A filter assembly 112 is affixed to the integrated circuit 104 by a connection layer 114, such as an adhesive or a weld. The filter assembly 112 includes a filter housing 116 that holds a particle filter 118, such as a hydrophobic fiber filter, a pore membrane filter, or another type of filter. For instance, the particle filter 118 can be affixed to the filter housing 116 by a layer of adhesive 120. The particle filter 118 can have openings sized such that particulate matter of a target size cannot pass through the particle filter 118. For instance, the particle filter can have openings with a diameter of less than about 100 nm. The filter housing 116 can be formed of a molded material, such as a molded plastic. The filter housing 116 holds the particle filter 118 in alignment with the photodetector 108 such that a cavity 122 is defined between the particle filter 118 and the integrated circuit 104. The cavity 122 is fluidically connected to a laterally-oriented flow channel through the filter housing 116 such that the cavity 122 and the flow channel together form a flow path for fluid to flow through the particle filter 118, discussed further with respect to FIGS. 2A-2D.

A light source 124, such as a light-emitting diode (LED), a vertical cavity surface emitting laser (VCSEL), a laser diode, or another type of light source, is electrically connected to the substrate 102, e.g., by solder balls, wire bonding, or another type of connection. The light source 124 is positioned such that light emitted from the light source 124 illuminates the particle filter 118. In the particulate matter sensor 100, the light source 124 is disposed on the substrate 102 and electrically connected to the substrate 102, e.g., by solder balls, wire bonding, or another type of connection. In some examples, the light source 124 can be mounted on a molded interconnect device that is connected to the substrate 102.

A sensor housing 126 is affixed to the substrate 102, e.g., by an adhesive 128. The sensor housing 126 can be formed of a molded material, such as a molded plastic. The sensor housing 126 and the substrate 102 define an interior space 130 within which the integrated circuit 104, the filter assembly 112, and the light source 124 are disposed.

The material or color, or both, of the sensor housing 126 can be selected such that light emitted from the light source 124 and incident on an interior surface 132 of the sensor housing 126 (shown as an arrow 135) is reflected by the interior surface 132 onto the particle filter 118 (shown as an arrow 137). For instance, the interior surface 132 of the sensor housing 126 can be reflective to light emitted by the light source 124, e.g., having at least 30% reflectivity to the wavelength(s) of light emitted by the light source 124. In some examples, the interior surface 132 of the sensor housing 126 can be coated with a reflective material, such as an aluminum film. In some examples, the sensor housing 126 can be shaped such that a large amount of light incident from the light source 124 is reflected onto the particle filter 118. For instance, a wall 133 of the sensor housing 126 can be angled and/or curved relative to the substrate 102 to cause light reflection onto the particle filter 118.

In some examples, the material or color, or both, of an exterior surface of the filter housing 116 can also be reflective to light emitted from the light source 124. In some examples, the exterior surface of the filter housing 116 can be coated with a reflective material, such as an aluminum film. In some examples, the material or color, or both, of an interior surface of the filter housing 116 can also be reflective, e.g., coated with a reflective material, such as an aluminum film.

In operation, light emitted from the light source 124 is incident on the particle filter 118 (e.g., via reflection from the interior surface 132 of the sensor housing 126). The photodetector 108 measures an amount of light transmitted through the particle filter 118 (shown as an arrow 139). As particle loaded fluid flows through the particle filter 118, particulate matter accumulates on or in the filter 118. The particulate matter on or within the particle filter 118 causes absorption, scattering, or both, of the light incident on the particle filter 118, reducing the amount of light transmitted through the particle filter 118. The change in intensity of the light transmitted through the particle filter 118 is an indication of the amount of particulate matter in the fluid.

In some examples, the volume between the integrated circuit 104 and the substrate 102 is filled with an underfill material 134, e.g., to reduce or prevent fluid flow between the integrated circuit 104 and the substrate 102. In some examples, a fillet 136 can be formed at the lateral edges of the integrated circuit 104 to reduce cross talk between the light source 124 and the photo sensor 108.

In the example particulate matter sensor 100 of FIG. 1, a second photodetector 140 is formed in the integrated circuit 104. The filter housing 116 holds a reference particle filter 142 in alignment with the second photodetector 140. A cavity 144 is defined between the reference particle filter 142 and the integrated circuit 104. However, the cavity 144 does not connect to a flow channel through the filter housing 116, so there is no flow path for fluid flow through the reference particle filter 142. In the example of FIG. 1, the reference particle filter 142 is the same piece of material as the particle filter 118. In some examples, the particle filter 118 and the reference particle filter 142 are formed of distinct pieces of material. In some examples, no reference particle filter is present. In the particulate matter sensor 100, the second photodetector 140 is formed in the same integrated circuit 104 as the photodetector 108. In some examples, the second photodetector 140 can be formed on a distinct integrated circuit from the integrated circuit 104 of the photodetector 108.

The reference particle filter 142 allows for correction of measurement error due to variability in the intensity of the light source 124. As particle-loaded fluid flows through the particle filter 118, particulate matter accumulates in or on the particle filter 118. For instance, for a porous membrane filter, particulate matter can accumulate on the surface of the filter; for a fibrous filter, particulate matter can accumulate on the surface and in the bulk of the filter. However, no fluid flows through the reference particle filter 142, so there is little to no particulate matter accumulation on the reference particle filter 142. In a system with no variability in the intensity of the light source, the amount of light transmitted through the reference particle filter 142 and detected by the photodetector 140 would be substantially constant over time. Variations in the amount of light detected by the photodetector 140 can indicate variability in the intensity of the light source and can be used to adjust the signal detected by the photodetector 108.

In some examples, a particulate matter sensor can include multiple light sources, such as two, three, four, or more than four light sources. For instance, two light sources can be positioned on opposite sides of the filter assembly 112, e.g., along a lateral symmetry line between the two photo sensors 108, 140 or aligned perpendicular to the lateral symmetry line. Four light sources can be positioned one on each side of the filter assembly. In some examples, multiple light sources can be positioned on each of one or more of the sides of the filter assembly, e.g., to provide a greater signal to the photodetectors 108, 140. The multiple light sources can emit each with substantially the same spectral distribution to enhance the total optical power available in the particulate matter sensor 100.

In some examples, multiple wavelengths can be used to enable the identification of different types of particulate matter (referred to as source apportionment). In some examples, each light source of multiple light sources can emit light of a different wavelength, e.g., light sources mounted symmetrically with respect to the photodetectors 108, 140, and the photodetectors 108, 140 can be configured to detect some or all of the wavelengths emitted by the multiple light sources. In some examples, one or more broad spectrum light sources, such as white LEDs, can be used to provided multiple wavelengths. For multiple wavelength sensing, the photodetectors 108, 140 can be divided into multiple regions, with each region covered with a wavelength filter to enable detection of specific wavelengths. For instance, the photodetectors 108, 140 can each be divided into a first region sensitive to infrared light (e.g., 880 nm wavelength light) and a second region sensitive to blue light (e.g., 470 nm light).

FIG. 2A shows a top view of a particulate matter sensor 200 having two light sources 124a, 124b positioned on opposite sides of the filter assembly 112. FIGS. 2B, 2C, and 2D show cross sections of the particulate matter sensor 200 along lines A-A′, B-B′, and C-C′, respectively. These cross sections depict the presence of a flow path for fluid flow through the particle filter 118 and the absence of a flow path such that fluid does not flow through the reference particle filter 142.

Referring to FIG. 2B, the cross section along line A-A′ shows the cavity 122 between the particle filter 118 and the integrated circuit 104 and the cavity 144 between the reference particle filter 142 and the integrated circuit 104. Referring to FIG. 2C, the cross section along line B-B′ shows a cross section of a laterally-oriented flow channel 202 fluidically connected to the cavity 122. No such flow channel exists for the reference particle filter, and the cavity 144 is not fluidically connected to any flow channel. Referring to FIG. 2D, cross section along line C-C′ shows that the flow channel 202 extends through the filter housing 116.

The cavity 122 and the laterally-oriented flow channel 202 together define a flow path that enables fluid to flow through the particle filter 118. As fluid flows through the particle filter 118, particulate matter from the fluid accumulates on the particle filter 118. The absence of a flow channel connected to the cavity 144 means that there is no flow path that enables fluid to flow through the reference particle filter 142, which minimizes particulate deposition onto the reference particle filter 142.

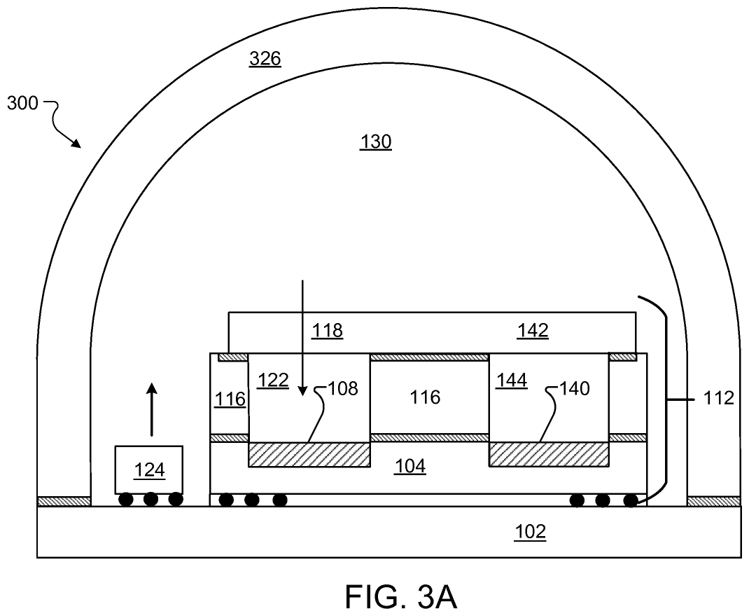

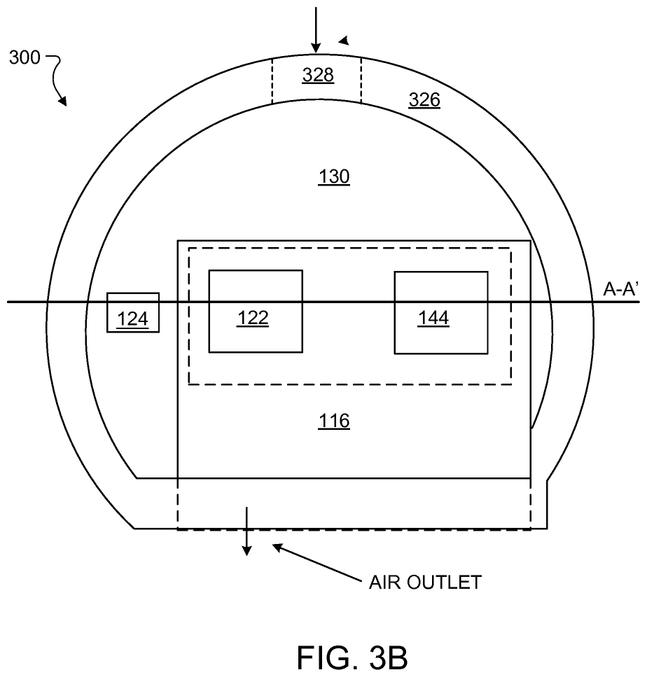

Referring to FIGS. 3A and 3B, an example particulate matter sensor 300 includes a sensor housing 326 having a curved cross sectional profile, such as a spherical shape, an elliptical shape, or a parabolic mirror shape. The curved shape of the sensor housing 326 helps to reflect light from the light source 124 toward the particle filter 118, e.g., the sensor housing 326 acts as an integrating sphere. A fluid inlet 328 formed in the sensor housing 326 provides a flow pathway for fluid to entire into the particulate matter sensor 300.

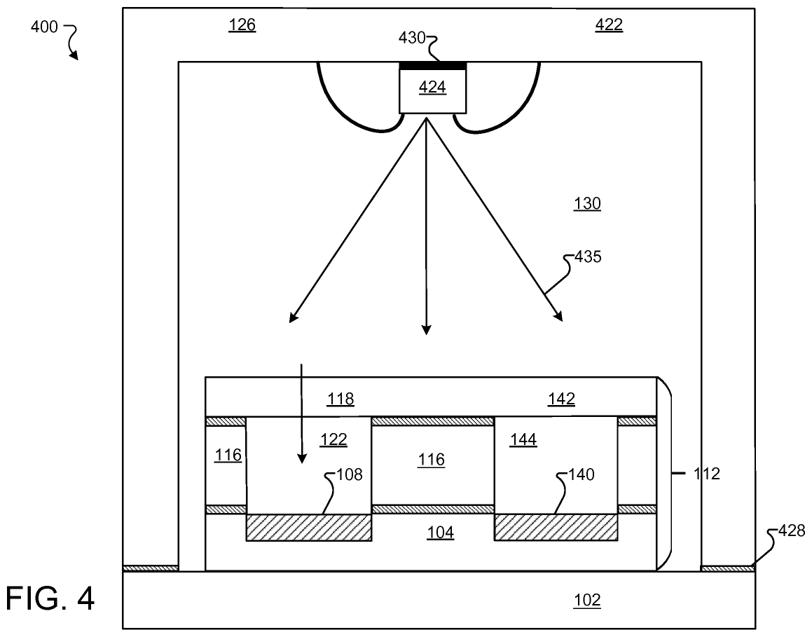

Referring to FIG. 4, an example particulate matter sensor 400 includes a sensor housing 426 having a wall 422 oriented substantially perpendicular to the substrate 102. A light source 424 is integrated into or affixed onto the wall 422, e.g., by an adhesive 430. To achieve this, the sensor housing 426 includes interconnect features (not shown), e.g., connected to the substrate 102 by a conductive adhesive 428. In areas of the sensor housing without interconnect features, a non-conductive adhesive is used. In this configuration, light emitted from the light source 424 (shown as arrows 435) is incident directly onto the particle filter 118 and the reference particle filter 142, which can increase the amount of light incident on the filter relative to configurations in which the light is reflected.

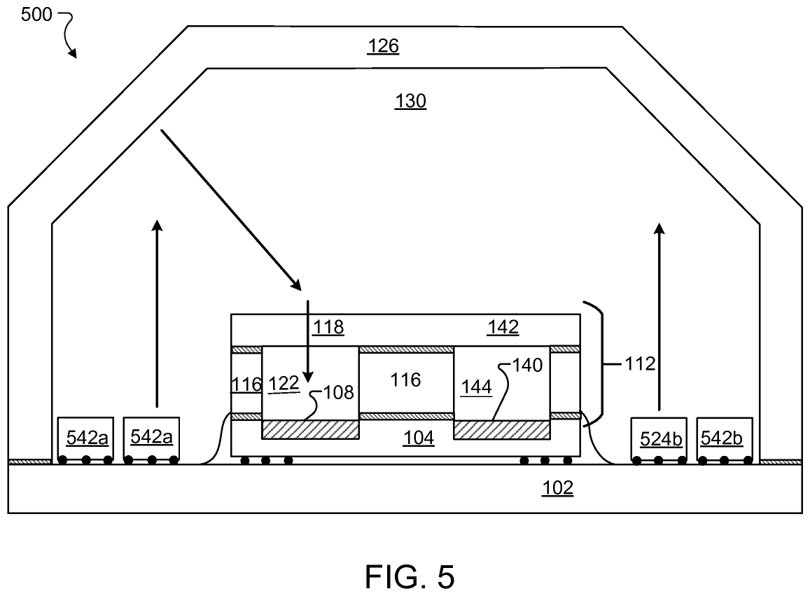

Referring to FIG. 5, an example particulate matter sensor 500 includes multiple light sources 524a, 524b. Multiple photodetectors 542a, 542b are disposed on the substrate 102 external to the filter assembly 112, and electrically connected to the substrate 102. For instance, the photodetectors 542a, 542b can be disposed to opposite sides of the filter assembly 112. The external photodetectors 542a, 542b can be used to measure reflection of light from the filters 118, 142, e.g., by alternating illumination of the sides of the filter assembly 112. In the example of FIG. 5, the particulate matter sensor 500 is shown as having generally a similar structure as the particulate matter sensor 100 of FIG. 1; however, external photodetectors can also be used in other sensor configurations, such as those shown in FIGS. 3 and 4. The configuration of FIG. 5, with multiple external photodetectors, can also be used without the use of a reference particulate filter (e.g., without the filter 142 and associated photodetector 140).

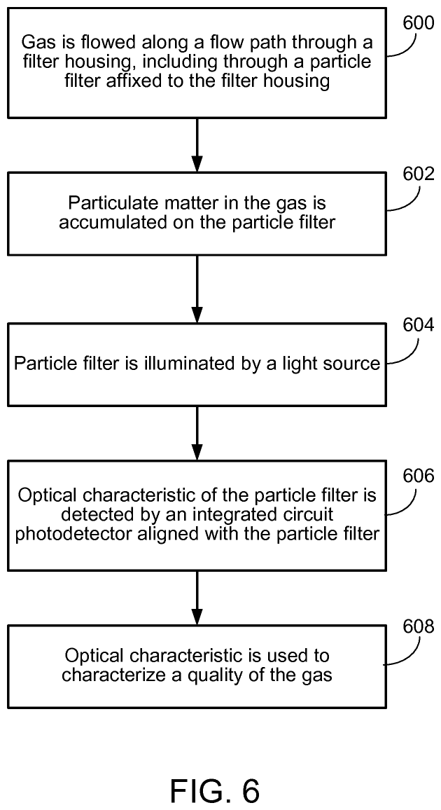

Referring to FIG. 6, in an example process for detecting particulate matter in a fluid, a fluid is flowed along a flow path through a filter housing, including through a particle filter affixed to the filter housing (600). The filter housing is affixed to an integrated circuit that is electrically connected to a substrate, such as a printed circuit board. Particulate matter in the fluid accumulates on the particle filter as the fluid flows through the particle filter (602). The particle filter is illuminated with light from a light source that is electrically connected to the substrate (604). For instance, light emitted from the light source can be incident on an interior surface of a sensor housing and reflected from the interior surface of the sensor housing onto the particle filter.

An optical characteristic of the particle filter is detected by a photodetector formed in the integrated circuit and aligned with the particle filter (606). The optical characteristic can include an amount of light transmitted through the particle filter or an absorption of the particle filter. The optical characteristic can include a rate of change of an optical characteristic, such as a rate of change in the amount of light transmitted through the particle filter or a rate of change in the absorption of the particle filter. The detected optical characteristic can be used to characterize a quality of the fluid (608), such as an air quality, e.g., an amount of particulate matter in the fluid (e.g., an amount of black carbon in the fluid).

The particulate matter sensor can form part of a microfluidic sensor system, described below. Over time, the filter can become full of particulate matter such that little to no light is transmitted through the filter. To increase the useful lifetime of the particulate matter sensor, the sensor system can be operated in sessions. Operation of the sensor system in a session can be stopped when a threshold is reached in measurement of the optical characteristic, such as a threshold noise level, a threshold change or percentage change in the absorption of the filter from the beginning of the session. If the fluid quality is poor (many particles in the fluid), the measurement time will be short. If the fluid is relatively clean (few particles in the fluid), the measurement time will be longer. With this approach, the number of measurement sessions the particulate matter sensor is capable of carrying out can be relatively independent of the particle concentration in the fluid.

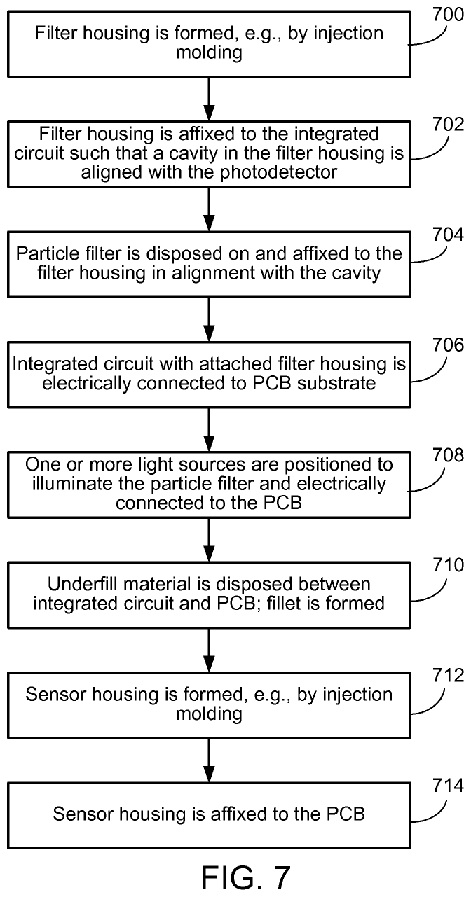

Referring to FIG. 7, in an example process for making a particulate matter sensor, a filter housing is formed, e.g., by a molding process, e.g., injection molding (700). The filter housing can be molded to include a cavity and a flow channel connected to the cavity and providing an outlet from the filter housing. In cases in which a reference particle filter is to be used, the filter housing can be molded to include a second cavity that is not connected to a flow channel. In some examples, the filter housing can be molded from a material that is reflective, e.g., greater than 30% reflective, to light of a wavelength to be used in the particulate matter sensor. In some examples, the filter housing is made such than an exterior surface of the housing, an interior surface of the housing, or both, are a reflective color, such as white. In some examples, the molded filter housing (e.g., the exterior surface, the interior surface, or both) is coated with a reflective layer, such as a layer of aluminum.

The filter housing is affixed to an integrated circuit including a photodetector, e.g., by an adhesive (702), such that the cavity formed in the filter housing is aligned with the photodetector. In cases in which a reference particle filter is to be used, two cavities are formed in the filter housing, and each cavity is aligned with a corresponding one of the photo detectors.

A particle filter is disposed on and affixed to the filter housing (704) in alignment with the cavity or cavities formed in the filter housing. In some examples, the filter housing is affixed to the integrated circuit prior to affixing the particle filter to the filter housing; in some examples, the particle filter is affixed to the filter housing prior to affixing the filter housing to the integrated circuit.

The integrated circuit with the attached filter housing is electrically connected to a printed circuit board (PCB) substrate (706). In cases in which a reference particle filter is to be used, the integrated circuit can include a second photodetector. In some examples, two integrated circuits each including a photodetector can be electrically connected to the PCB. In some examples, the integrated circuit(s) can be connected to the substrate by TSVs, a backside redistribution layer, and solder balls. In some examples, the integrated circuit(s) can be connected to the substrate by wire bonding.

One or more light sources, such as LEDs or VCSELs, are positioned on and electrically connected to the PCB (708). For instance, the one or more light sources are disposed on the PCB and electrically connected to the PCB by TSVs, a backside redistribution layer, and solder balls, or by wire bonding. In some examples, the light sources can be electrically connected to the PCB substrate prior to connecting the integrated circuit.

An underfill material is disposed between the integrated circuit(s) and the PCB and a fillet can be formed at the lateral edges of the integrated circuit(s) (710).

A sensor housing is formed, e.g., by a molding process, e.g., injection molding (712). The sensor housing can be molded such that a wall of the sensor housing is angled, such that when assembled, the angled wall can help reflect light from the light source onto the particle filter. The sensor housing can be molded into a partial spherical shape.

The sensor housing is affixed to the PCB (714), e.g., by an adhesive, such that the integrated circuit(s), the filter housing, and the light source are disposed within an interior space defined by the sensor housing and the PCB.

In cases in which the one or more light sources are disposed on the sensor housing, the light sources can be affixed to the sensor housing, e.g., by an adhesive, and electrical connection features of the sensor housing can be electrically connected to the PCB.

The particulate matter sensors described here can be fabricated in parallel, e.g., for efficient and low-cost manufacturing. For instance, multiple particulate matter sensors, e.g., hundreds of sensors, can be fabricated in parallel on a single PCB substrate, and the printed circuit board substrate with the multiple sensors formed thereon can then be singulated into individual dies.

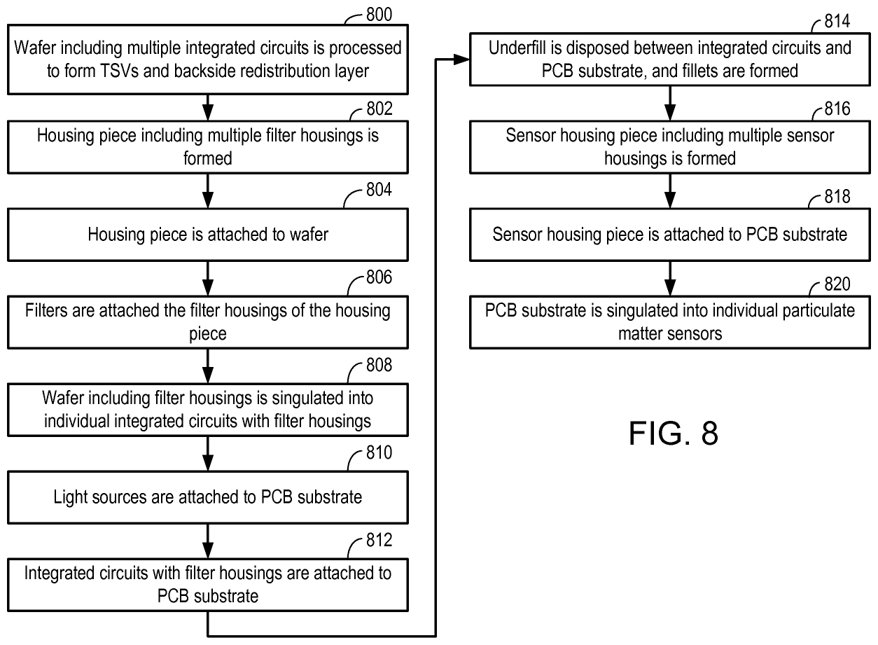

Referring to FIG. 8, in an example process for parallel manufacture of multiple particulate matter sensors, a wafer including multiple integrated circuits, each integrated circuit including a photodetector, is processed (800). The processing can include forming TSVs and a backside redistribution layer.

A housing piece including multiple filter housings is formed (802), e.g., by injection molding, and attached to the wafer (804). The housing piece can be similarly sized to the wafer and the housing piece can be attached such that each filter housing is aligned with a corresponding integrated circuit of the wafer. Filters are attached to the filter housings in the molded piece (806). The wafer including the housing piece is singulated into individual integrated circuits (808), each integrated circuit having an attached filter housing.

Multiple light sources are attached to a PCB substrate (810). The integrated circuits with attached filter housings are attached to the PCB substrate (812). An underfill material is disposed between each integrated circuit and the PCB substrate, and a fillet is formed at the lateral edges of each integrated circuit (814).

A sensor housing piece including multiple sensor housings is formed (816), e.g., by injection molding, and attached to the PCB substrate (818). The PCB substrate is singulated into multiple individual particulate matter sensors (820).

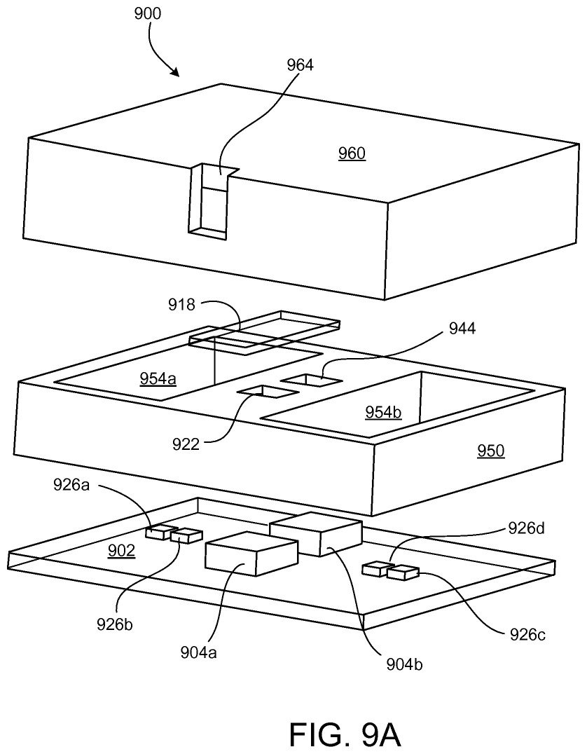

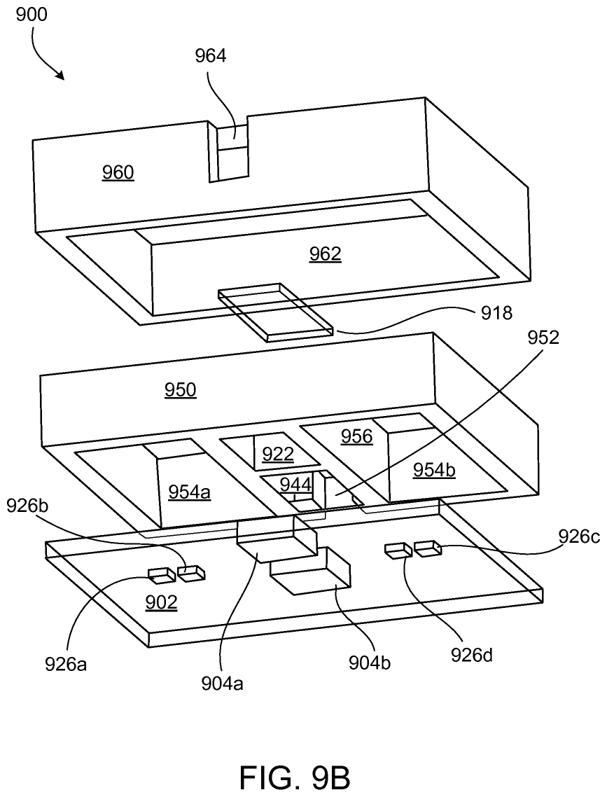

FIGS. 9A and 9B are exploded views of an example particulate matter sensor 900. In this example, two integrated circuits 904a, 904b each including a photodetector are disposed on and electrically connected to a PCB substrate 902. Four light sources 926a-726d (referred to collectively as light sources 926) are also disposed on and electrically connected to the PCB substrate 902. For instance, two of the light sources 926a, 926c can emit light at a first wavelength (e.g., 900 nm) and the other two light sources can emit light at a second wavelength 926b, 926d (e.g., 500 nm), enabling source apportionment. The light sources 926 are positioned such that each light source can generate a similar light intensity on both photodetectors.

A bottom molded piece 950 is disposed on and affixed to the PCB substrate 902, e.g., by an adhesive. The bottom molded layer 950 is molded to define cavities 922, 944 and two interior regions 954a, 954b. A lateral flow channel 952 connected to the cavity 922 is also defined in the bottom molded layer 950. The bottom molded layer 950 is disposed on the PCB substrate 902 such that the cavities 922, 944 are aligned with the photodetectors in the integrated circuits 904a, 904b. A filter 918 is disposed on and affixed to the bottom molded layer 950 to cover the top opening of both cavities 922, 944, forming a particle filter and a reference particle filter. The presence of walls 956 of the bottom molded layer 950 between the light sources 924 and the integrated circuits 904 with the photodetectors can help reduce cross-talk between the light sources and the photodetectors.

A top molded piece 960 is disposed on and affixed to the top surface of the bottom molded piece 950. The top molded piece 960 defines an interior region 962. The interior regions 954a, 954b defined by the bottom molded piece 950 and the interior region 962 defined by the top molded piece 960 together form an interior space within with light from the light sources 924 can travel. A fluid inlet 964 is defined in the top molded piece to allow fluid to enter into the particulate matter sensor 900.

The adhesive used in assembling the particulate matter sensor 900 can be applied in only two planes: the plane connecting the bottom molded piece 950 to the PCB substrate 902 and the plane connecting the top molded piece 960 to the bottom molded piece 950. Adhesive can also be applied to affix the filter 918 to the bottom molded layer 950.

The particulate matter sensors described here can be incorporated into microfluidic particulate matter sensor systems. The integration of the filter with the integrated circuit including the photodetector, and the placement of the light source and the integrated circuit on the same PCB substrate enables the particulate matter sensors to be compact. For instance, particulate matter sensor systems incorporating the particulate matter sensors described here can have a height of less than about 3 mm, e.g., less than about 2 mm; and a footprint of less than about 10×10 mm².

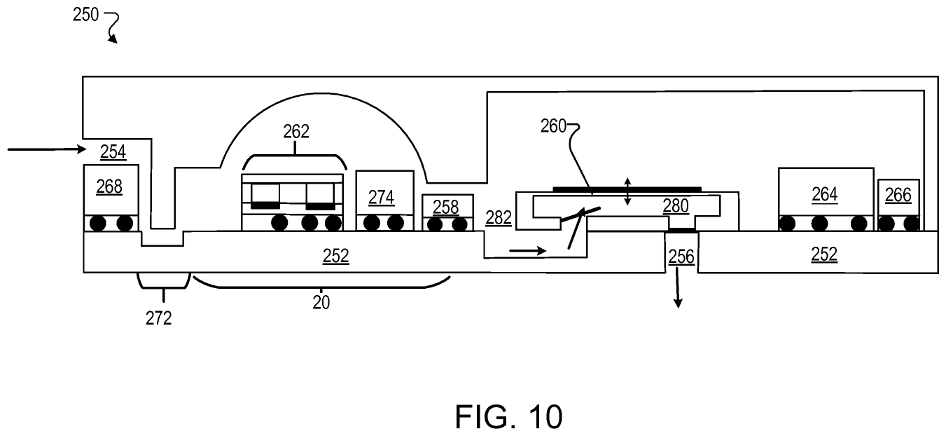

Referring to FIG. 10, a particulate matter sensor 20 such as those described above is incorporated into a particulate matter sensor system 250. A microfluidic flow path is defined through the particulate matter sensor system 250 from an inlet 254, through the particulate matter sensor 20, and out through an outlet 256. The entire particulate matter sensor system 250, including the particulate matter sensor 20, is built on the same PCB substrate 252.

The example particulate matter sensor 20, which includes a filter assembly 262, is structured similarly to the particulate matter sensor 100 of FIG. 1. Other configurations of the particulate matter sensor are also compatible with the particulate matter sensor system 250, such as the configurations shown in FIGS. 2-4. A light source 274 of the particulate matter sensor 20 is controlled by a microcontroller 258 disposed on and electrically connected to the PCB substrate 252.

A cover layer 270 is disposed over the PCB substrate 252 such that an interior space between the cover layer 270 and the PCB substrate 252 define the flow path through the sensor system 250. For instance, the cover layer 270 can be a molded piece, e.g., a molded plastic piece. In the example of the particulate matter sensor system 250, the cover layer 270 serves both to define the flow path and as the sensor housing (e.g., the sensor housing 126 of FIG. 1) of the particulate matter sensor 20. For instance, the cover layer 270 can have an interior surface that is reflective to light emitted by the light source 274 of the particulate matter sensor 20.

A fluid circulation device 260 is disposed on the PCB substrate 252 and drives fluid flow through the sensor system 250. The fluid circulation device can be, e.g., a pump, a fan, a heater, an ultrasonic nozzle, or another device capable of causing fluid flow through the sensor system 250. In the example of FIG. 9, the fluid circulation device 260 is a piezoelectric membrane pump. The fluid circulation device 260 is controlled by a controller 264, coupled to one or more capacitors and inductors 266, all of which are disposed on and electrically connected to the PCB substrate 252.

The particulate matter sensor system 250 can include a heater 268 positioned at the inlet 254 of the microfluidic flow path. The heater 268, e.g., a resistive heater, can heat the fluid flowing into the sensor system 250, e.g., to reduce condensation of humidity in the air flowing through the system. In some examples, the heater 268 can function as a flow sensor to detect a mass flow rate of fluid in the sensor system 250. For instance, the mass flow rate of fluid can be determined based on a change in temperature of the fluid flowing through the heater 268.

The particulate matter sensor system 250 can include a size separation feature 272, such as an impactor, for preventing particles above a threshold size from flowing through the rest of the microfluidic flow path. For instance, particles above a threshold size may not be of interest for air quality measurements, but would cause a significant change in optical characteristics of the filter of the particulate matter sensor 20 if allowed to flow through the rest of the microfluidic flow path. Separating out these larger particles can enable more precise measurements of particulate matter in a desired size range.

In some particulate matter sensor systems, a filter is present upstream from an inlet to a chamber 280 of the fluid circulation device 260, e.g., in a region 282. Such a filter can prevent particulate matter from adversely affecting the operation of the fluid circulation device 260. In particulate matter sensor systems incorporating filter-based particulate matter sensors, such as the particulate matter sensor system 250 of FIG. 10, no filter is present in the region 282, e.g., because the filter of the filter-based particulate matter sensor 20 serves to prevent particulate matter from progressing downstream through the microfluidic flow path in the sensor system.

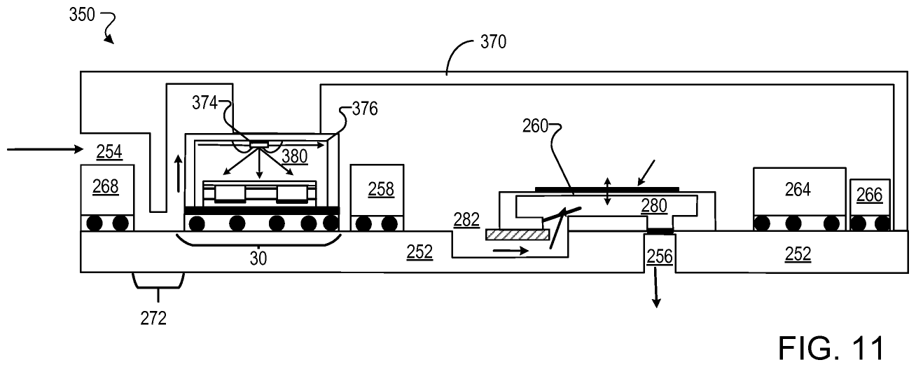

Referring to FIG. 11, a particulate matter sensor 30 such as those described above is incorporated into a particulate matter sensor system 350. In the particulate matter sensor system 350, a cover layer 370 disposed over the PCB substrate 252 defines a flow path through the sensor system 350. The cover layer 370 is distinct from a sensor housing 376 that defines an interior space 380 for the particulate matter sensor 30. In this configuration, an interior surface of the sensor housing 376 can be reflective to light emitted by a light source 374 of the particulate matter sensor 30. However, the light from the light source 374 does not reach the interior surface of the cover layer 370.

The example particulate matter sensor 30 is structured similarly to the particulate matter sensor 400 of FIG. 4. Other configurations of the particulate matter sensor are also compatible with the particulate matter sensor system 350, such as the configurations shown in FIGS. 1-3 and FIG. 5.

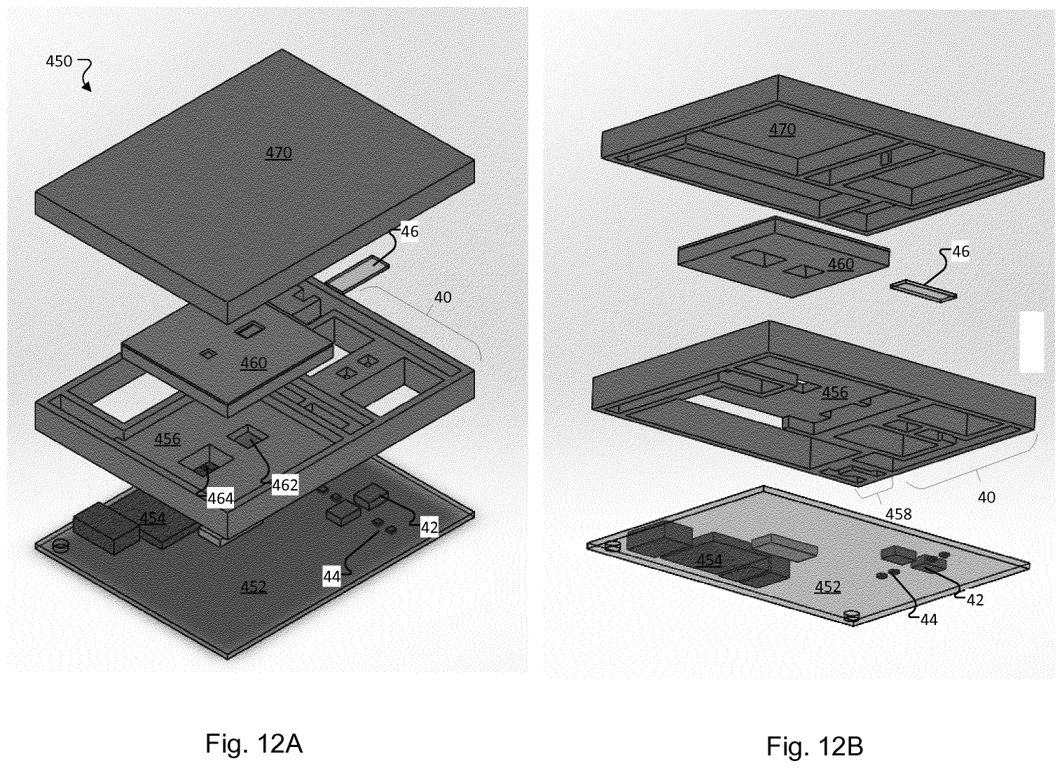

Referring to FIGS. 12A and 12B, a particulate matter sensor 40 such as those described above, including photodetectors 42, light sources 44, and a filter 46, is incorporated into a particulate matter sensor system 450. The sensor system 450 includes a PCB substrate 452 on which components 454 of the sensor system are disposed, such as controllers, capacitors, and inductors. A base part 456, e.g., a molded component, is formed to define portions of various components of the sensor system 450. For instance, the base part 456 can define the filter assembly of the particulate matter sensor 40. The base part 456 can also define an inlet 462 into a fluid circulation device 460 and an outlet 464 from the fluid circulation device. A cover layer 470 is disposed over the base part 456 and connected to the base part 456, e.g., by a form closure. The base part 456, the cover layer 470, or both define microfluidic channels of the flow path through the sensor system 450. In some examples, components of the sensor system 450, such as a size separation feature 458, can be defined by the structure of the base part 456, the cover layer 470, or both. For instance, in the example of FIG. 12A, the size separation feature 458 is formed between the base part 456 and the PCB substrate 452 and defined by the shape of the base part 456.

In the configuration of the particulate matter sensor system 450, fluid passes first through a chamber of the sensor system 450 in which the photodetectors 42 are disposed, meaning that particulate matter in the fluid will not pass through a reference filter and also will not pass over the light sources 44. This configuration can help prevent contamination of the reference filter and adverse effects that can result from particulate matter contamination of the light sources 44.

The fabrication of the particulate matter sensors and sensor systems described here is compatible with high-throughput, low-cost manufacturing techniques such as injection molding and microelectronics processing and packaging techniques, enabling rapid and economical manufacturing of these sensors and sensor systems.

Additional description of particulate matter sensor systems can be found in PCT Application No. [[Attorney Docket No. 45768-0011WO1/120-17]], the contents of which are incorporated here by reference in their entirety.

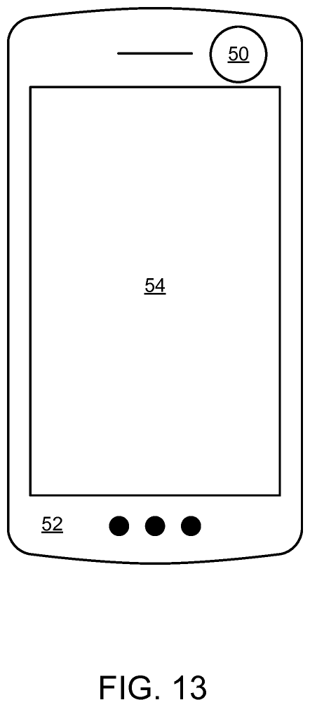

Referring to FIG. 13, a particulate matter sensor system 50 such as those described above can be incorporated into a mobile computing device 52, such as a mobile phone (as shown), a tablet, or a wearable computing device. The particulate matter sensor system 50 can be operable by a user, e.g., under control of an application executing on the mobile computing device 52, to conduct air quality testing. A test result can be displayed on a display screen 54 of the mobile computing device 52, e.g., to provide substantially immediate feedback to the user about the quality of the air in the user's environment.

The particulate matter sensor systems described here can also be incorporated into other devices, such as air purifiers or air conditioning units; or used for other applications such as automotive applications or industrial applications.

A number of embodiments have been described. Nevertheless, it will be understood that various modifications may be made without departing from the spirit and scope of the invention. For example, some of the steps described above may be order independent, and thus can be performed in an order different from that described.

Other implementations are also within the scope of the following claims.

1. An apparatus for sensing particulate matter in a fluid, the apparatus comprising:
a substrate;
an integrated circuit electrically connected to the substrate, the integrated circuit including a photodetector;
a filter assembly comprising:
a particle filter aligned with the photodetector, and
a filter housing for the particle filter, the filter housing defining a flow path for fluid through the particle filter; and
a light source electrically connected to the substrate and positioned to illuminate the particle filter.

2. The apparatus of claim 1, in which the filter assembly is affixed to the integrated circuit.

3. The apparatus of claim 1, in which the filter assembly is affixed to the substrate.

4. The apparatus of claim 1, in which the substrate comprises a printed circuit board.

5. The apparatus of claim 1, in which the light source is disposed on the substrate.

6. The apparatus of claim 5, comprising multiple light sources disposed on the substrate, a first light source disposed to a first side of the filter assembly and a second light source disposed to a second side of the filter assembly.

7. The apparatus of claim 5, comprising:
multiple light sources disposed on the substrate; and
multiple photodetectors disposed on the substrate,
in which each of the multiple light sources is positioned to illuminate each photodetector with light of a substantially similar intensity.

8. The apparatus of claim 1, comprising multiple photodetectors disposed on the substrate, a first photodetector disposed to a first side of the filter assembly and a second photodetector disposed to a second side of the filter assembly.

9. The apparatus of claim 1, comprising a sensor housing affixed to the substrate, the sensor housing and the substrate defining an interior space in which the integrated circuit, the filter assembly, and the light source are disposed, optionally in which a cross section of the sensor housing has a curved profile.

10. (canceled)

11. The apparatus of claim 9, comprising a layer of a reflective material disposed on an interior surface of the sensor housing and/or in which an interior surface of the sensor housing has a reflectivity of at least 30% to light emitted by the light source.

12. The apparatus of claim 9, in which the light source is positioned to illuminate the sensor housing such that light reflected from the sensor housing illuminates the particle filter.

13. The apparatus of claim 9, in which the light source is disposed on an interior wall of the sensor housing.

14. (canceled)

15. The apparatus of claim 1, in which the integrated circuit comprises a second photodetector, and in which the filter assembly comprises a reference particle filter aligned with the second photodetector, optionally in which the filter housing does not define a flow path for fluid through the reference particle filter.

16. (canceled)

17. The apparatus of claim 1, in which the integrated circuit is electrically connected to the substrate by through silicon vias, a backside redistribution layer, and solder balls, optionally comprising an underfill material disposed between the integrated circuit and the substrate and/or a fillet disposed at one or more edges of the integrated circuit.

18.-19. (canceled)

20. The apparatus of claim 1, in which the light source comprises a broad spectrum light source, and in which the photodetector includes a first region configured to detect a first wavelength emitted from the broad spectrum light source and a second region configured to detect a second wavelength emitted from the broad spectrum light source.

21. The apparatus of claim 1, in which the light source is a first light source configured to emit light a first wavelength, and comprising a second light source configured to emit light at a second wavelength; and
in which the photodetector is configured to detect the first wavelength and the second wavelength.

22. A method for detecting particulate matter in a fluid, the method comprising:
flowing a fluid containing particulate matter through a flow path defined by a filter housing, including flowing the fluid through a particle filter disposed on the filter housing;
illuminating the particle filter with light from a light source electrically connected to a substrate; and
detecting an optical characteristic of the particle filter by a photodetector formed in an integrated circuit electrically connected to the substrate, the photodetector being aligned with the particle filter.

23. The method of claim 22, in which detecting an optical characteristic of the particle filter comprises detecting an absorption of the particle filter.

24. The method of claim 22, in which detecting an optical characteristic of the particle filter comprises detecting a rate of change in the optical characteristic.

25. (canceled)

26. The method of claim 22, comprising stopping the flow of fluid when a threshold change in the optical characteristic of the particle filter is detected.

27. A method for making an apparatus for sensing particulate matter in a fluid, the method comprising:
electrically connecting an integrated circuit including a photodetector to a printed circuit board substrate;
disposing a filter housing on the printed circuit board substrate such that a particle filter disposed on the filter housing is aligned with the photodetector of the integrated circuit, the filter housing defining a flow path for fluid through the particle filter; and
electrically connecting a light source to the printed circuit board substrate such that the light source is positioned to illuminate the particle filter.

28.-33. (canceled)

34. The method of claim 27, comprising forming the filter housing by a molding process, optionally in which forming the filter housing comprises forming multiple cavities in the filter housing.

35.-40. (canceled)

41. The method of claim 27, in which affixing a filter housing to an integrated circuit includes affixing a housing piece including multiple filter housings to a wafer including multiple integrated circuits such that each of one or more of the filter housings is aligned with a corresponding integrated circuit, optionally comprising one or more of:
singulating the wafer into multiple pieces, each piece including an integrated circuit with affixed filter housing,
electrically connecting the integrated circuit to the printed circuit board substrate comprises electrically connecting the multiple pieces each including an integrated circuit to the printed circuit board substrate,
singulating the printed circuit board substrate into multiple pieces.

42.-44. (canceled)

45. A sensing system for sensing particulate matter in a fluid, the sensing system comprising:
an inlet microfluidic channel;
a particle sensing apparatus comprising:
a substrate;
an integrated circuit electrically connected to the substrate, the integrated circuit including a photodetector;
a filter assembly comprising:
a particle filter aligned with the photodetector, and
a filter housing for the particle filter, the filter housing defining a sensing microfluidic channel for fluid through the particle filter, the sensing microfluidic channel being fluidically connected to the inlet microfluidic channel; and
a light source electrically connected to the substrate and positioned to illuminate the particle filter;
an outlet fluidically connected to the sensing microfluidic channel; and
a fluid circulation component configured to induce fluid flow from the inlet microfluidic channel, through the sensing microfluidic channel, and out the outlet.

46. The sensing system of claim 45, in which the fluid circulation component comprises one or more of a pump, a fan, a heater, and an ultrasonic nozzle.
